(19) United States
(12) Patent Application Publication
(10) Pub. No.: US 2002/0127829 A1
(43) Pub. Date: Sep. 12, 2002

(54) Solution processing apparatus and solution processing method

(76) Inventor: Yoshinori Marumo, Nirasaki-shi (JP)

Correspondence Address: PILLSBURY WINTHROP, LLP, P.O. BOX 10500, MCLEAN, VA, 22102, US

(21) Appl. No.: 10/086,524

(22) Filed: Mar. 4, 2002

(30) Foreign Application Priority Data
Mar. 6, 2001 (JP) P2001-62262

(51) Int. Cl. H01L 21/20; H01L 21/36; H01L 21/31; H01L 21/469

(52) U.S. Cl. 438/509; 438/765

(57) ABSTRACT

A holder holding a wafer descends and the wafer comes in contact with a plating solution. In this state, the wafer is heated by a resistance heating element disposed in the holder so that the temperature of the wafer becomes gradually higher from its outer circumference to its center part. Then, voltage is applied between an anode electrode and the wafer to apply the plating on a face to be plated of the wafer.

### BACKGROUND OF THE INVENTION

1. Field of the Invention

The present invention relates to a solution processing apparatus and a solution processing method for performing solution processing on a substrate such as a semiconductor wafer.

2. Description of the Related Art

Conventionally, as an apparatus for forming a metal layer on a surface of a substrate such as a semiconductor wafer (hereinafter simply referred to as “wafer”), for example, a physical vapor deposition processing apparatus (PVD processing apparatus) by which the metal layer is formed with a vapor phase has been used. However, in recent years, as the density of a semiconductor device is improving, the use of a plating apparatus by which the metal layer is formed with a liquid phase is becoming the mainstream in terms of the film-formation speed.

FIG. 23 is a schematic vertical sectional view showing a plating apparatus in a conventional art.

As shown in FIG. 23, a plating apparatus 200 is composed of a plating solution tank 201 mainly containing a plating solution therein and a wafer holder 202 for holding a wafer W. To plate the wafer W in the plating apparatus 200, the wafer holder 202 holding the wafer W descends first so that the wafer W comes in contact with the plating solution in the plating solution tank 201. Then, voltage is applied between an anode electrode 203 disposed in the plating solution tank 201 and a cathode electrode 204 disposed in the wafer holder 202 and the plating is applied on the wafer W.

Here, in the plating apparatus 200 as described above, since the plating is applied on the wafer W by feeding electric power from the cathode electrode 204 to an outer circumference of the wafer W, the current density of a center part and the outer circumference of the wafer become different. Therefore, the plating tends to be applied thicker on the outer circumference than on the center part of the wafer W.

In a case of preventing the difference in current density between the center part and the outer circumference of the wafer as described above, that is, the ununiformity of the current density on a surface of the wafer, the provision of a shielding plate formed of dielectric material in the plating solution tank 201 is the mainstream at present.

However, even if the shielding plate is provided, the uniformity of the current density on the surface of the wafer W cannot be improved effectively, and there is a possibility that the wafer W is ununiformly plated. Particularly, as a diameter of the wafer W becomes larger, the ununiformity tends to become remarkable.

### BRIEF SUMMARY OF THE INVENTION

It is an object of the present invention to provide a solution processing apparatus and a solution processing method capable of improving the uniformity of solution processing performed on a substrate.

In order to achieve the aforesaid object, a solution processing apparatus of the present invention comprises: a processing solution tank for containing a processing solution therein; a holder for holding a substrate; a first electrode coming in contact with the substrate held by the holder; a second electrode between which and the first electrode voltage is applied; and a temperature adjusting mechanism disposed in the holder for adjusting the temperature of the substrate.

Since the solution processing apparatus of the present invention comprises the temperature adjusting mechanism disposed in the holder for adjusting the temperature of the substrate, the uniformity of the solution processing performed on the substrate can be improved.

The temperature adjusting mechanism of the aforesaid solution processing apparatus preferably includes a heating member for heating the substrate. The temperature adjusting mechanism includes the heating member, which can enhance the solution processing speed.

The temperature adjusting mechanism of the aforesaid solution processing apparatus can also include a cooling member for cooling the substrate. The temperature adjusting mechanism includes the cooling member, which can reduce the solution processing speed.

The temperature adjusting mechanism of the aforesaid solution processing apparatus preferably includes a heating member controller for controlling the heating member in a manner in which the temperature of a part where solution processing is difficult becomes higher than the temperature of a part where solution processing is easy. The temperature adjusting mechanism includes the heating member controller, which can surely improve the uniformity of the solution processing performed on the substrate.

The aforesaid solution processing apparatus can further comprise: a solution processing measurer for measuring degrees of solution processing performed on the part of the substrate where solution processing is easy and solution processing performed on the part where solution processing is difficult; and an optimal temperature calculator for calculating the optimal temperature of the part where solution processing is difficult based on a measurement result of the solution processing measurer, and the heating member controller can also control the heating member in a manner in which the temperature of the part where solution processing is difficult becomes the optimal temperature. Since the solution processing apparatus further comprises the solution processing measurer and the optimal temperature calculator, and the heating member controller controls the heating member in the manner in which the temperature of the part where solution processing is difficult becomes the optimal temperature, the uniformity of the solution processing performed on the substrate can be improved more securely.

In the aforesaid solution processing apparatus, the part where solution processing is easy is an outer circumference of the substrate, for example, and the part where solution processing is difficult is a center part of the substrate, for example. When the part where solution processing is easy is the outer circumference of the substrate and the part where solution processing is difficult is the center part of the substrate, if the aforesaid solution processing apparatus is used, the degrees of solution processing performed on the outer circumference and the center part of the substrate can be equalized.

The heating member of the aforesaid solution processing apparatus is preferably formed in a ring shape. By forming the heating member in the ring shape, the temperature of the substrate can be controlled in a ring shape.

A plurality of the heating members of the aforesaid solution processing apparatus are preferably disposed. By disposing the plural heating members, the temperature of the substrate can be partially controlled.

As the substrate used in the aforesaid solution processing apparatus, for example, a semiconductor wafer is named. In this case, the heating member preferably heats a rear face of the semiconductor wafer. The semiconductor wafer is used as the substrate and the rear face of the semiconductor wafer is heated by the heating member, which enable the temperature of the semiconductor wafer to be controlled efficiently.

As the heating member of the aforesaid solution processing apparatus, a resistance heating element can be used. By using the resistance heating element as the heating member, the heating member can be provided at low cost and formed into a predetermined shape easily.

As the heating member of the aforesaid solution processing apparatus, a heating lump can be used. By using the heating lump as the heating member, the increasing speed of the temperature of the substrate can be enhanced.

As the processing solution used in the aforesaid solution processing apparatus, for example, a plating solution is named. By using the plating solution as the processing solution, the substrate can be plated.

A solution processing method of the present invention comprises: a heating solution processing step of heating the substrate and supplying current to the substrate to perform solution processing on the substrate in a state in which a substrate is in contact with a processing solution. Since the solution processing method of the present invention comprises the heating solution processing step of heating the substrate and supplying the current to the substrate to perform solution processing on the substrate in the state in which the substrate is in contact with the processing solution, the uniformity of solution processing performed on the substrate can be improved.

Another solution processing method of the present invention comprises: a cooling solution processing step of cooling the substrate and supplying current to the substrate to perform solution processing on the substrate in a state in which a substrate is in contact with a processing solution; and a heating solution processing step of heating the substrate and supplying the current to the substrate to perform solution processing on the substrate in a state in which the substrate on which solution processing has been performed is in contact with the processing solution. The solution processing method of the present invention comprises the cooling solution processing step of cooling the substrate and supplying current to the substrate to perform solution processing on the substrate in the state in which the substrate is in contact with the processing solution, and the heating solution processing step of heating the substrate and supplying the current to the substrate to perform solution processing on the substrate in the state in which the substrate on which solution processing has been performed is in contact with the processing solution, which can improve a filling property of solution processing performed on the substrate. Further, the uniformity of the solution processing performed on the substrate can be improved.

The cooling solution processing step of the aforesaid solution processing method is preferably a step of cooling the substrate in a manner in which the temperature of the substrate becomes 5° C. to 15° C. and the heating solution processing step is preferably a step of heating the substrate in a manner in which the temperature of the substrate becomes 18° C. to 30° C. Since the cooling solution processing step is the step of cooling the substrate in the manner in which the temperature of the substrate becomes 5° C. to 15° C. and the heating solution processing step is the step of heating the substrate in the manner in which the temperature of the substrate becomes 18° C. to 30° C., the filling property of solution processing performed on the substrate can be surely improved.

The heating solution processing step of the aforesaid solution processing method is preferably performed in a state in which the temperature of a part of the substrate where solution processing is difficult is higher than the temperature of a part of the substrate where solution processing is easy. By performing the heating solution processing step in the state in which the temperature of the part of the substrate where solution processing is difficult is higher than the temperature of the part where solution processing is easy, the uniformity of the solution processing performed on the substrate can be surely improved.

The heating solution processing step of the aforesaid solution processing method includes: a solution processing measuring step of measuring degrees of solution processing performed on the part where solution processing is easy and solution processing performed on the part where solution processing is difficult; an optimal temperature calculating step of calculating an optimal temperature of the part where solution processing is difficult based on a measurement result of the solution processing measuring step; and a heating controlling step of controlling heating in a manner in which the temperature of the part where solution processing is difficult becomes the optimal temperature calculated in the optimal temperature calculating step. The heating solution processing step includes the solution processing measuring step, the optimal temperature calculating step, and the heating controlling step so that the uniformity of the solution processing performed on the substrate can be further improved.

In the aforesaid solution processing method, the part where solution processing is easy is an outer circumference of the substrate, for example, and the part where solution processing is difficult is a center part of the substrate, for example. When the part where solution processing is easy is the outer circumference of the substrate and the part where solution processing is difficult is the center part of the substrate, if the aforesaid solution processing method is used, degrees of solution processing performed on the outer circumference and the center part of the substrate can be equalized.

### BRIEF DESCRIPTION OF THE DRAWINGS

FIG. 1 is a schematic vertical sectional view showing a plating apparatus according to a first embodiment.

FIG. 2 is a schematic plan view showing the inside of the plating apparatus according to the first embodiment.

FIG. 3 is a schematic vertical sectional view showing a holder according to the first embodiment.

FIG. 4 is a schematic sectional plan view showing the holder according to the first embodiment.

FIG. 5 is a schematic plan view showing the inside of the holder according to the first embodiment.

FIG. 6 is a flow chart showing the flow of plating processing performed in the plating apparatus according to the first embodiment.

FIG. 7A to FIG. 7P are schematic views showing plating steps according to the first embodiment.

FIG. 8 is a schematic chart showing the relation between the temperature and each part of a wafer according to the first embodiment.

FIG. 9 is a schematic view showing the inside of a plating apparatus according to a second embodiment.

FIG. 10A and FIG. 10B are schematic views showing states of measuring the film thickness of the wafer according to the second embodiment.

FIG. 11 is a flow chart showing the flow of plating processing performed in the plating apparatus according to the second embodiment.

FIG. 12 is a schematic view showing the inside of a plating apparatus according to a third embodiment.

FIG. 13 is a flow chart showing the flow of plating processing performed in the plating apparatus according to the third embodiment.

FIG. 14A to FIG. 14J are schematic vertical sectional views showing plating steps according to the third embodiment.

FIG. 15 is a schematic vertical sectional view showing a holder according to a fourth embodiment.

FIG. 16 is a schematic plan view showing the inside of the holder according to the fourth embodiment.

FIG. 17 is a schematic vertical sectional view showing a holder according to a fifth embodiment.

FIG. 18 is a schematic plan view showing the inside of the holder according to the fifth embodiment.

FIG. 19 is a schematic vertical sectional view showing a Peltier element according to the fifth embodiment.

FIG. 20 is a flow chart showing the flow of plating processing performed in a plating apparatus according to the fifth embodiment.

FIG. 21 is a schematic view showing a state of a plated wafer according to the fifth embodiment.

FIG. 22 is a schematic plan view showing the inside of a holder according to a variation.

FIG. 23 is a schematic vertical sectional view showing a plating apparatus in a conventional art.

### DETAILED DESCRIPTION OF THE INVENTION

(First Embodiment)

A plating apparatus according to the first embodiment of the present invention will be explained below.

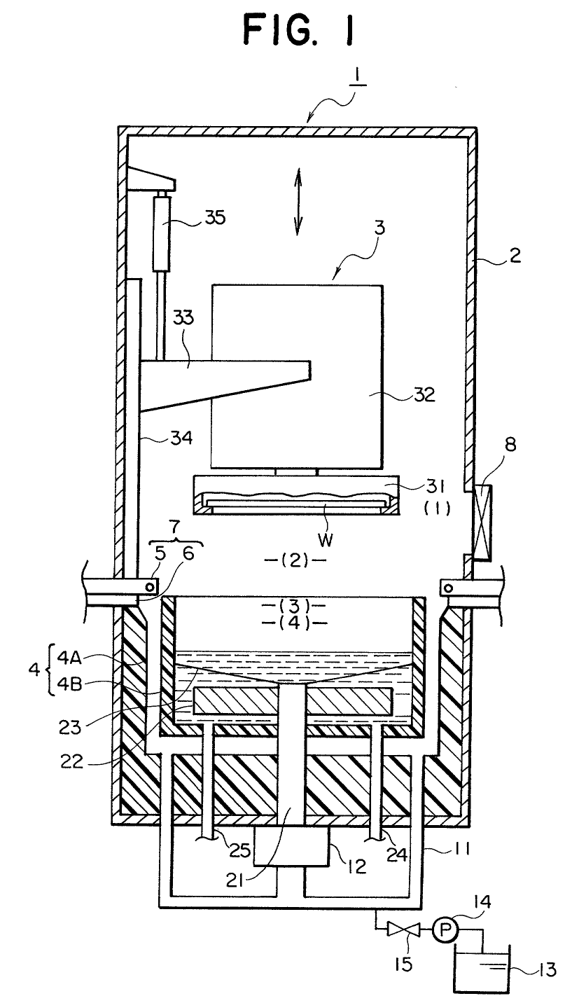

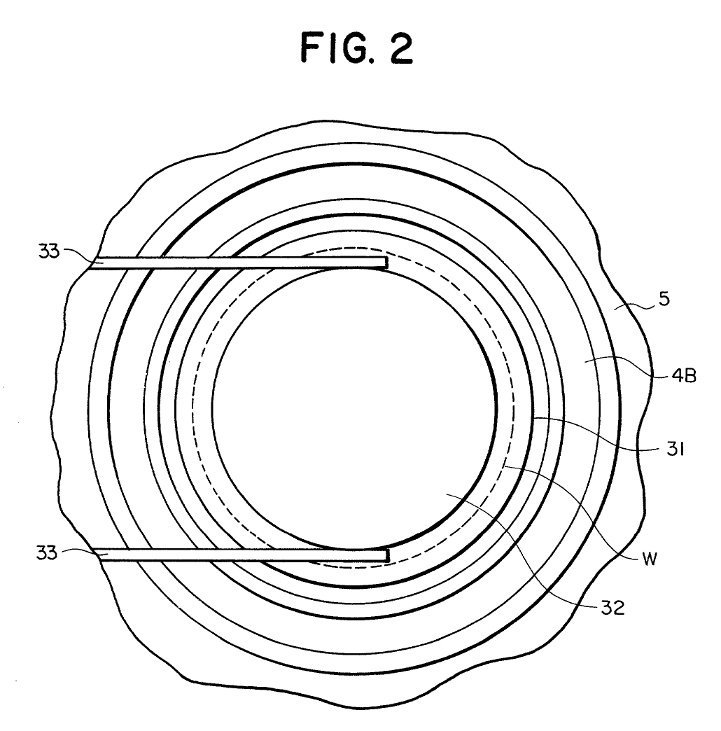

FIG. 1 is a schematic vertical sectional view showing the plating apparatus according to the embodiment, and FIG. 2 is a schematic plan view showing the inside of the plating apparatus according to the embodiment.

As shown in FIG. 1 and FIG. 2, a plating apparatus 1 includes a housing 2 of entirely sealed construction. The housing 2 is formed of corrosion resistant material such as resin.

In the housing 2, a driver 3 for holding a wafer W and a plating solution tank 4 (processing solution tank) for containing a plating solution therein are disposed. In this embodiment, the driver 3 is disposed immediately above the plating solution tank 4.

In the housing 2 near an upper part of the plating solution tank 4, a separator 7 including therein a cleaning nozzle 5 and an exhaust hole 6 disposed under the cleaning nozzle 5 is disposed. At the center of the separator 7, a through hole is provided so that the wafer W held by the driver 3 can move between a carrying position (1) and a plating position (4) which will be described later. Further, in the housing 2 near the carrying position (1) which will be described later, a gate valve 8 for carrying the wafer W into/out from the plating apparatus 1 is provided.

The plating solution tank 4 is a double tank composed of an outer tank 4A and an inner tank 4B disposed in the outer tank 4A concentrically.

The outer tank 4A is formed in a substantially cylindrical shape with its upper face being open and its bottom face being closed. A pipe 11 is connected to a bottom of the outer tank 4A. A pump 12 is disposed between the pipe 11 and an ejection pipe 21 which will be described later. By the operation of the pump 12, the plating solution discharged from the inner tank 4B and stored in the outer tank 4A is supplied to the inner tank 4B again. To the pipe 11, a tank 13 containing the plating solution therein is connected via a pump 14 and a valve 15. The pump 14 operates and the valve 15 opens, which causes the plating solution in the tank 13 to be supplied into the inner tank 4B.

The inner tank 4B is formed in a substantially cylindrical shape with its upper face being open and its bottom face being closed, similarly to the outer tank 4A. The ejection pipe 21 for ejecting the plating solution from a bottom face side of the inner tank 4B to the upper face protrudes in the inner tank 4B.

Around the ejection pipe 21, an anode electrode 22 (second electrode) in a substantially discoidal shape is disposed concentrically to the inner tank 4B. The anode electrode 22 is electrically connected to a not-shown outside power source outside the housing 2.

Between an outer circumference of an end of the ejection pipe 21 and the inner tank 4B, a dividing film 23 for dividing the inner tank 4B vertically is disposed above the anode electrode 22. The plating solution is supplied into an area upper than the dividing film 23 in the inner tank 4B from the ejection pipe 21, and the plating solution is supplied into an area lower than the dividing film 23 in the inner tank 4B from a circulating pipe 24, which will be described later. The dividing film 23 is formed in a manner that an ion can passes through it while impurities which occur when the anode electrode 22 is dissolved and bubbles of, for example, oxygen and hydrogen which occur during the plating cannot pass through it.

The circulating pipes 24 and 25 are provided at positions eccentric from the center of the bottom face of the inner tank 4B. Between the circulating pipes 24 and 25, a not-shown pump is disposed. By the operation of the pump, the plating solution is supplied from the circulating pipe 24 and discharged from the circulating pipe 25.

The driver 3 is composed of a holder 31 for holding the wafer W and a motor 32 for rotating the wafer W together with the holder 31 in a substantially horizontal plane.

To the motor 32, an ascending/descending mechanism for allowing the driver 3 to ascend/descend with respect to the plating solution tank 4 is mounted. Specifically, the ascending/descending mechanism is composed of, for example, supporting beams 33 mounted on an outer case of the motor 32, for supporting the driver 3, a guide rail 34 mounted on an inner wall of the housing 2, and a cylinder 35 capable of contracting/expanding vertically for allowing the supporting beams 33 to ascend/descend along the guide rail 34. By the drive of the cylinder 35, the driver 3 supported by the supporting beams 33 moves upward/downward along the guide rail 34 so that the wafer W ascends/descends.

Specifically, by the ascending/descending mechanism, the wafer W ascends/descends between mainly four positions of different height on a center axis of the plating solution tank 4, that is, a carrying position (1) for carrying the wafer W, a wafer cleaning position (2) for cleaning the plating applied on the wafer W with a cleaning solution such as pure water, a spin drying position (3) for performing spin drying so as to remove excessive plating solution and moisture, and a plating position (4) for plating a face to be plated of the wafer W. The carrying position (1) and the wafer cleaning position (2) are upper than a plating solution level when the inner tank 4B of the plating solution tank 4 is filled with the plating solution, and the spin drying position (3) and the plating position (4) are lower than the plating solution level.

Next, the holder 31 according to the embodiment will be explained.

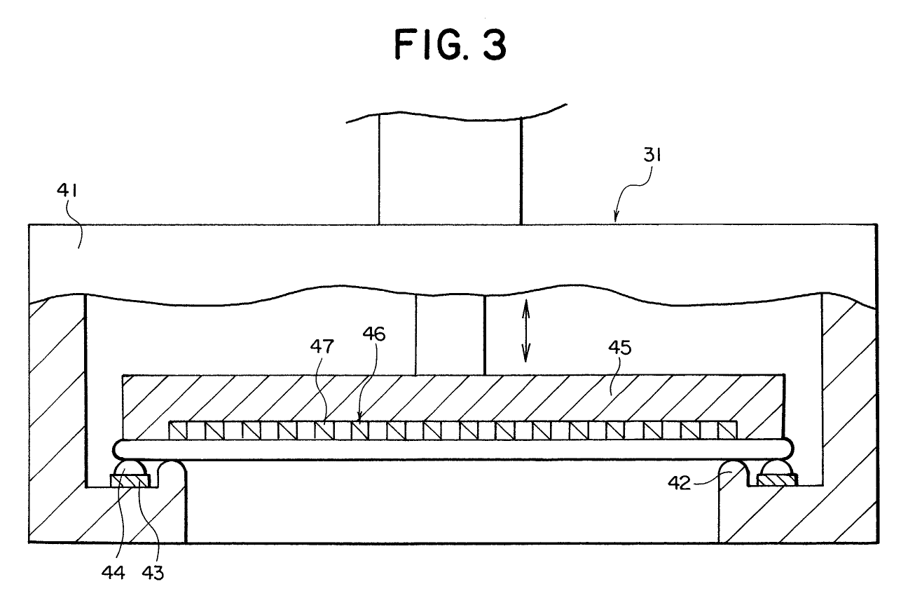

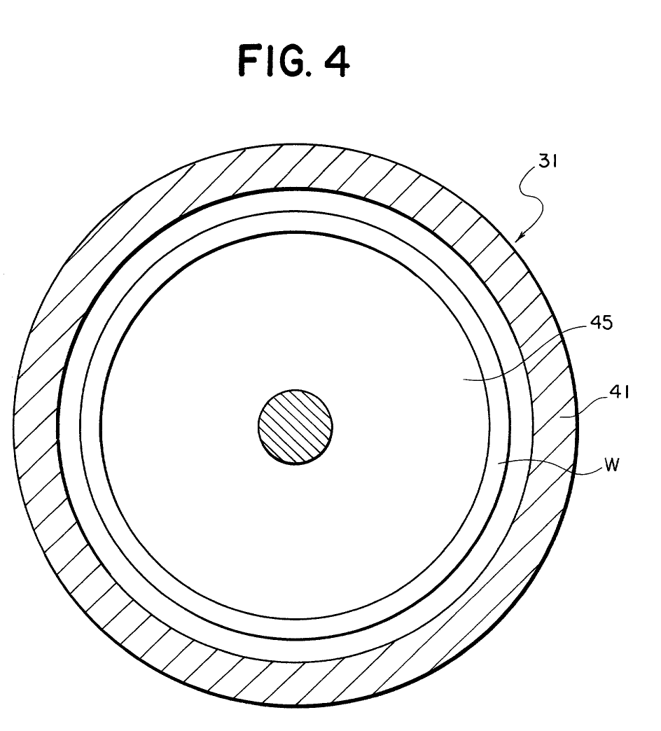

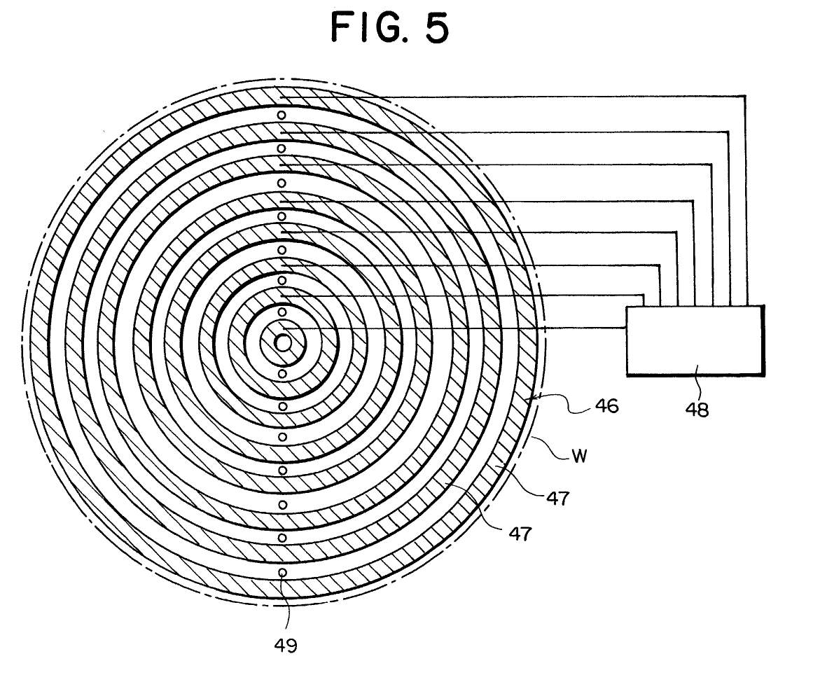

FIG. 3 is a schematic vertical sectional view showing the holder 31 according to the embodiment, FIG. 4 is a schematic sectional plan view showing the holder 31 of the embodiment, and FIG. 5 is a schematic plan view showing the inside of the holder 31 of the embodiment.

As shown in FIG. 3 to FIG. 5, the holder 31 includes a holder container 41 in a substantially cylindrical shape having an opening in a substantially circular shape at its bottom. In the holder container 41, one sheet of the wafer W is held substantially horizontally. The wafer W held in the holder container 41 comes in contact with the plating solution via the opening.

It should be noted that the wafer W of the embodiment is held by the holder 31 in a so-called face-down method in which the face to be plated is directed downward. On the face to be plated of the wafer W, slots and holes for the formation of wiring or interlayer connection are formed. Further, on the face to be plated of the wafer W, a so-called seed layer, which is a thin film made of the same material as the plating, is formed. This seed layer is formed by, for example, a film-formation processing apparatus, such as a PVD processing apparatus, disposed in another system. The seed layer is formed so that voltage applied to a cathode electrode 43, which will be described later, is also applied to the face to be plated of the wafer W.

On an edge of the opening in the holder container 41, a seal portion 42 is formed. When the wafer W is held, the seal portion 42 is pressed by a resistance heating element holder 45, which will be described later, via the wafer W. The seal portion 42 is pressed so that the plating solution is prevented from entering into the holder container 41.

In the holder container 41, the cathode electrode 43 (first electrode) for feeding electric power to the face to be plated of the wafer W is disposed. The cathode electrode 43 is electrically connected to a not-shown outside power source. Further, on the cathode electrode 43, semi-spherical contacts 44 for coming in contact with an outer circumference of the face to be plated of the wafer W are provided to protrude at equally-divided, for example, 128 positions. The contacts 44 are formed in the semi-spherical shape so that a certain area of the wafer W comes in contact with each of the contacts 44.

In the holder container 41, the resistance heating element holder 45 for holding a resistance heating element 46 which will be explained below, capable of ascending/descending with respect to the holder container 41 is disposed. In the resistance heating element holder 45, the resistance heating element 46 (heating member) such as nichrome wires or kanthal wires is disposed so as to come in direct contact with a rear face of the wafer W.

The resistance heating element 46 is composed of a plurality of resistance heating elements 47 formed in a ring shape. Each of the resistance heating elements 47 is held in the resistance heating element holder 45 centrically and substantially horizontally.

To the resistance heating element 46, a resistance heating element controller 48 (heating member controller) disposed outside the housing 2 for controlling the resistance heating element 46 is electrically connected. Specifically, for example, the resistance heating element controller 48 is electrically connected to each of the resistance heating elements 47 and heating values can be varied for each of the resistance heating elements 47. The plural resistance heating elements 47 and the controller 48 are disposed so that the temperature of the wafer W can be partially adjusted (zone control). In other words, for example, the temperature of a center part of the wafer W can be made higher than the temperature of its outer circumference by making a heating value of the resistance heating element 47, which is in contact with the center part of the rear face of the wafer W, higher than a heating value of the resistance heating element 47, which is in contact with the outer circumference, by the resistance heating element controller 48.

Between each of the resistance heating elements 47, temperature sensors 49 such as thermocouples or radiation thermometers are disposed. The temperature sensors 49 measure the temperature of the wafer W by coming in direct or indirect contact with the rear face of the wafer W. Since the temperature sensors 49 are provided, the temperature of each part of the wafer W can be measured, which makes it easier to bring each part of the wafer W to an optimal temperature. Further, abnormality in temperature of the wafer W due to failure of the resistance heating elements 47 or the like can be found and the zone control of the temperature of the wafer W can be surely performed.

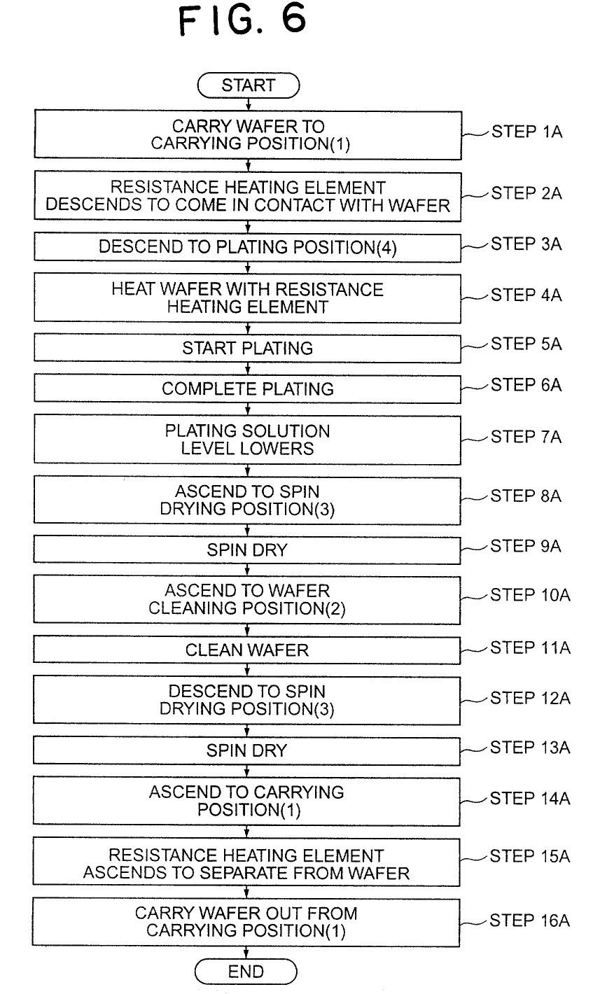

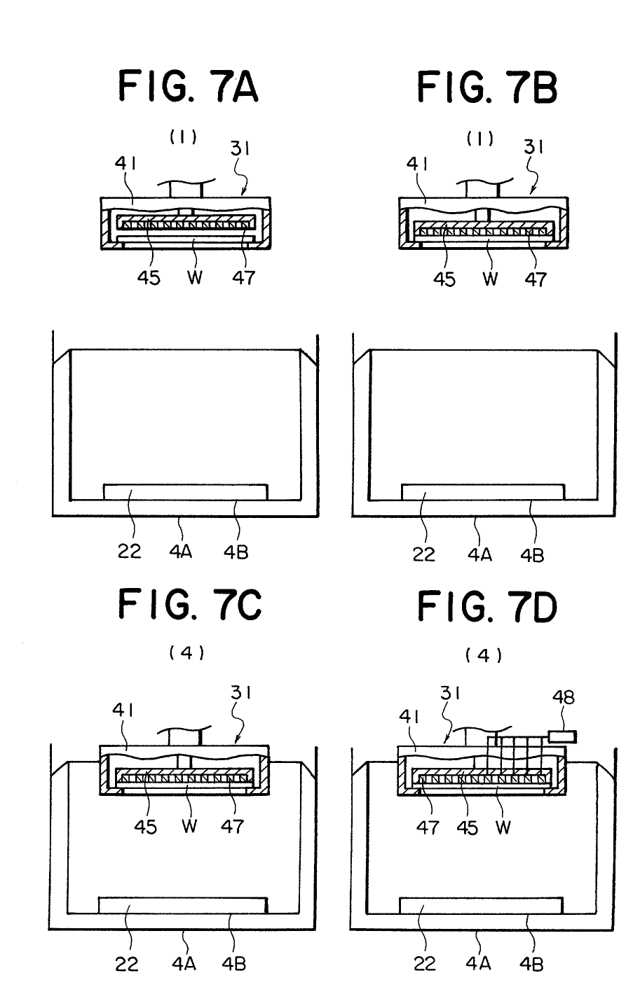

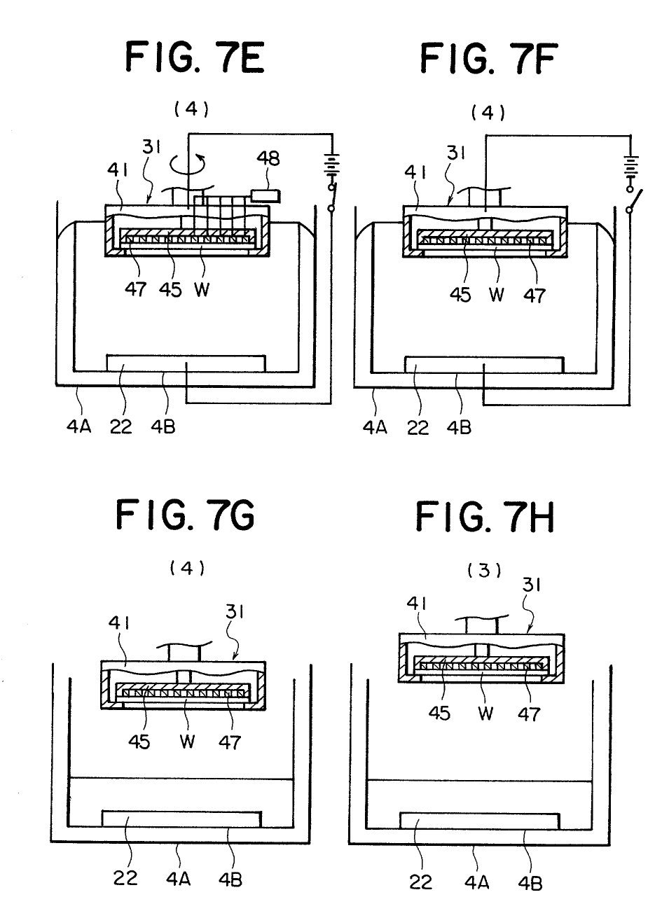

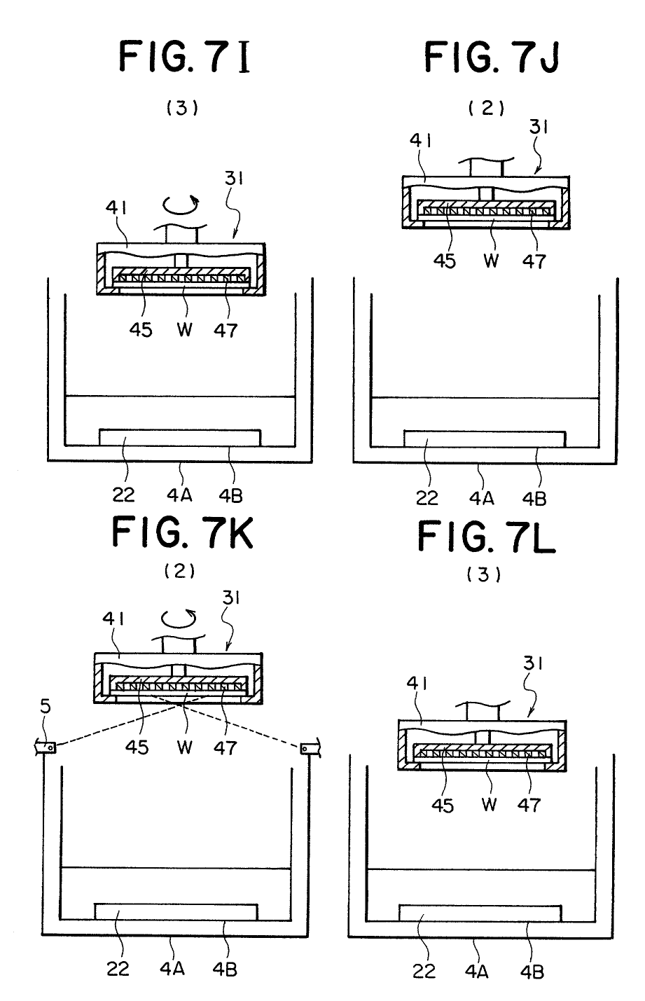

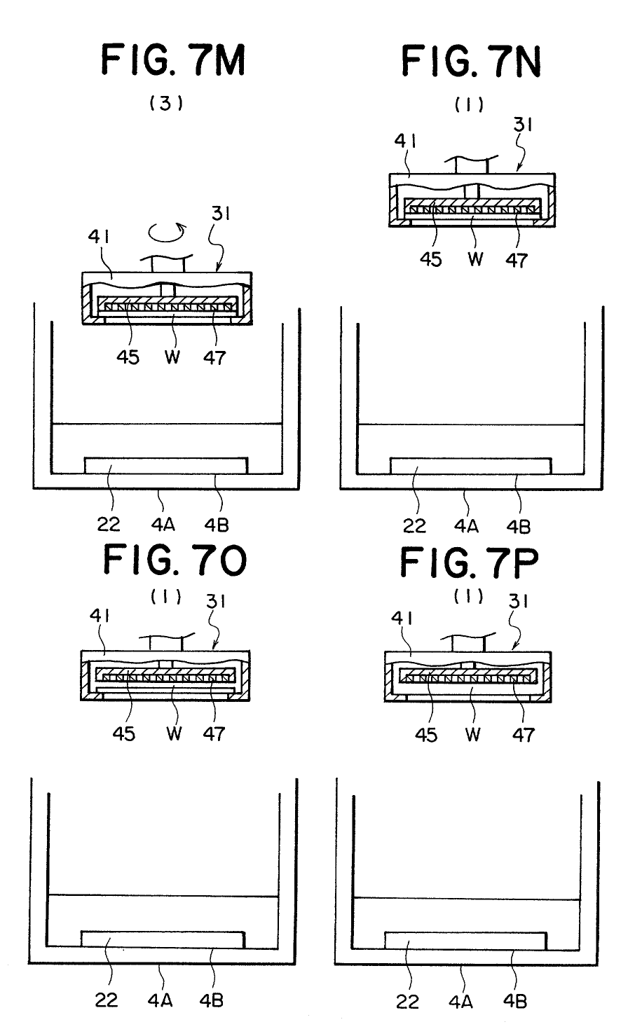

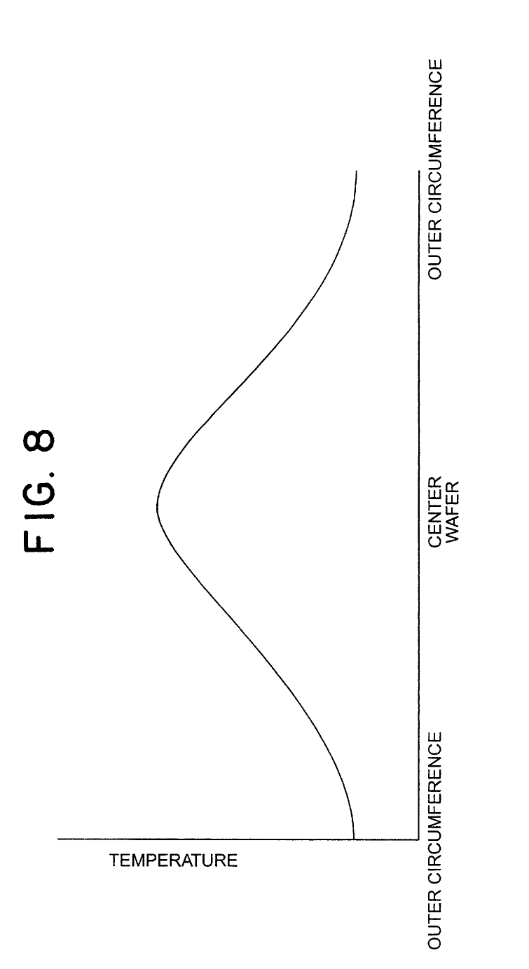

The flow of the plating processing in the plating apparatus 1 will be explained below with reference to FIG. 6 and FIG. 7A to FIG. 7P. FIG. 6 is a flow chart showing the flow of the plating processing performed in the plating apparatus 1 according to the embodiment, and FIG. 7A to FIG. 7P are schematic views showing plating processing steps according to the embodiment. FIG. 8 is a schematic chart showing the relation between each part of the wafer W and the temperature in the embodiment.

First, the gate valve 8 provided in a sidewall of the plating apparatus 1 opens and a not-shown carrying arm holding an unprocessed wafer W by sucking its rear face extends into the holder 31. Then, as shown in FIG. 7A, the wafer W is positioned at the carrying position (1), and the carrying arm separates from the wafer W. Thereafter, the carrying arm contracts and the gate valve 8 is closed (Step 1A).

After the gate valve 8 is closed, the resistance heating element holder 45 descends with respect to the holder container 41 and each of the resistance heating elements 47 comes in contact with the rear face of the wafer W, as shown in FIG. 7B. By this contact, the seal portion 42 is pressed (Step 2A).

In this state, the driver 3 descends by the drive of the cylinder 35 so as to position the wafer W at the plating position (4), as shown in FIG. 7C (Step 3A). Incidentally, the inner tank 4B of the plating solution tank 4 is filled with the plating solution. Further, even when the wafer W is positioned at the plating position (4), the seal portion 42 of the holder 31 is in the pressed state and therefore the plating solution does not enter into the holder container 41.

After the wafer W is position at the plating position (4), as shown in FIG. 7D, the rear face of the wafer W is heated while the heating value of each of the resistance heating elements 47 is controlled by the resistance heating element controller 48 in a manner that the temperature of an area which is difficult to plate becomes higher than the temperature of an area which is easy to plate (Step 4A).

It should be noted that the area which is easy to plate is, specifically, the outer circumference of the wafer W, for example, and the area which is difficult to plate is, specifically, the center part of the wafer W, for example. In addition, in this embodiment, the wafer W is heated by each of the resistance heating elements 47 in the manner that the temperature of the wafer W becomes gradually higher from the outer circumference to the center part of the wafer W, as shown in FIG. 8. Furthermore, the temperature of each part of the wafer W is set at an optimal temperature which has been previously obtained by plating a wafer for measurement such as a dummy wafer. The wafer W has excellent heat conductivity and is capable of conducting the heat given from its rear face to the face to be plated efficiently.

After the temperature of the wafer W is stabilized, in this state, voltage is applied between the anode electrode 22 and the wafer W so as to plate the face to be plated of the wafer W, as shown in FIG. 7E (Step 5A). Incidentally, when the face to be plated of the wafer W is plated, the motor 32 is driven to plate the wafer W while rotating the wafer W.

In this embodiment, although the voltage is applied from the outer circumference of the wafer W, the face to be plated of the wafer W is plated in a state that the temperature of the wafer W becomes gradually higher from its outer circumference to its center part, and hence the uniformity of the plating applied on the face to be plated of the wafer W can be improved.

In other words, the temperature of the wafer W becomes gradually higher from its outer circumference to its center part so that the film-formation speed becomes substantially uniform from the center part to the outer circumference. The relation between the temperature of the wafer W and the film-formation speed will be explained below. When the temperature of the wafer W rises, the viscosity of the plating solution near the face to be plated decreases. Due to the decrease in viscosity of the plating solution, the moving speed of ions, which are material forming the plating, in the plating solution increases, which enables the ions to reach the vicinity of the face to be plated of the wafer W easily. Further, since most of the ions reached the vicinity of the face to be plated come to have more energy than the activation energy, the reactivity increases. For this reason, the film-formation speed increases. Accordingly, when the temperature of the wafer W rises, the film-formation speed increases. Therefore, by making the temperature of the wafer W become gradually higher from its outer circumference to its center part, the film-formation speed can be made substantially uniform from the center part to the outer circumference, and the uniformity of the plating to be applied on the face to be plated of the wafer W can be improved even when the voltage is applied from the outer circumference of the wafer W.

Moreover, since the temperature of each part of the wafer W is set at the optimal temperature which has been previously obtained with the wafer for measurement, the uniformity of the plating can be further improved. Furthermore, as described above, since the film-formation speed of the plating increases when the wafer W is heated, the plating of a desired thickness can be applied in a short time.

After the plating of sufficient thickness is applied on the face to be plated of the wafer W, as shown in FIG. 7F, the heating by each of the resistance heating elements 47 is stopped as well as the application of the voltage is stopped so as to complete the application of the plating (Step 6A). At this time, the drive of the motor 32 stops and the rotation of the wafer W stops.

Subsequently, the pump 14 operates as well as the valve 15 opens, a predetermined quantity of the plating solution is returned to the tank 13, and the plating solution level in the plating solution tank 4 lowers, as shown in FIG. 7G (Step 7A).

After the plating solution level lowers, the driver 3 ascends by the drive of the cylinder 35 to position the wafer W at the spin drying position (3), as shown in FIG. 7H (Step 8A).

In this state, as shown in FIG. 7I, the wafer W is rotated by the drive of the motor 32 so that the spin drying for removing an excessive plating solution from the wafer W is performed (Step 9A).

After the spin drying is sufficiently performed, the driver 3 ascends by the drive of the cylinder 35 so as to position the wafer W at the wafer cleaning position (2), as shown in FIG. 7J (Step 10A).

After the wafer W is positioned at the wafer cleaning position (2), as shown in FIG. 7K, the wafer W is rotated in a substantially horizontal plane by the drive of the motor 32 as well as the cleaning solution such as pure water is ejected from the cleaning nozzle 5 which is included in the separator 7 to the plating applied on the wafer W so as to clean the plating applied on the wafer W (Step 11A).

After the plating applied on the wafer W is cleaned, the driver 3 descends by the drive of the cylinder 35 to position the wafer W at the spin drying position (3), as shown in FIG. 7L (Step 12A).

After the wafer W is positioned at the spin drying position (3), as shown in FIG. 7M, the wafer W is rotated by the drive of the motor 32 and the spin drying is performed (Step 13A).

Thereafter, the driver 3 ascends by the drive of the cylinder 35 to position the wafer W at the carrying position (1), as shown in FIG. 7N (Step 14A).

In this state, as shown in FIG. 70, the resistance heating element holder 45 ascends with respect to the holder container 41 and the resistance heating element 46 separates from the rear face of the wafer W (Step 15A).

Then, the gate valve 8 opens and the not-shown carrying arm extends to hold the plated wafer W by suction. After the carrying arm holds the wafer W, the carrying arm holding the wafer W contracts so that the wafer W is carried out from the plating apparatus 1, as shown in FIG. 7P (Step 16A).

Thus, the plating processing in the plating apparatus 1 is completed.

(Second Embodiment)

The second embodiment of the present invention will be explained below. Incidentally, the contents of this and subsequent embodiments overlapping those of the preceding embodiment will be omitted in some cases.

In this embodiment, explained is an example in which the thickness (film thickness) of the plating of each part of the wafer is measured, the optimal temperature for improving the uniformity of the plating is calculated based on the measured film thickness, and each of the resistance heating elements is controlled at the calculated optimal temperature by the resistance heating element controller, while the plating is applied on the wafer.

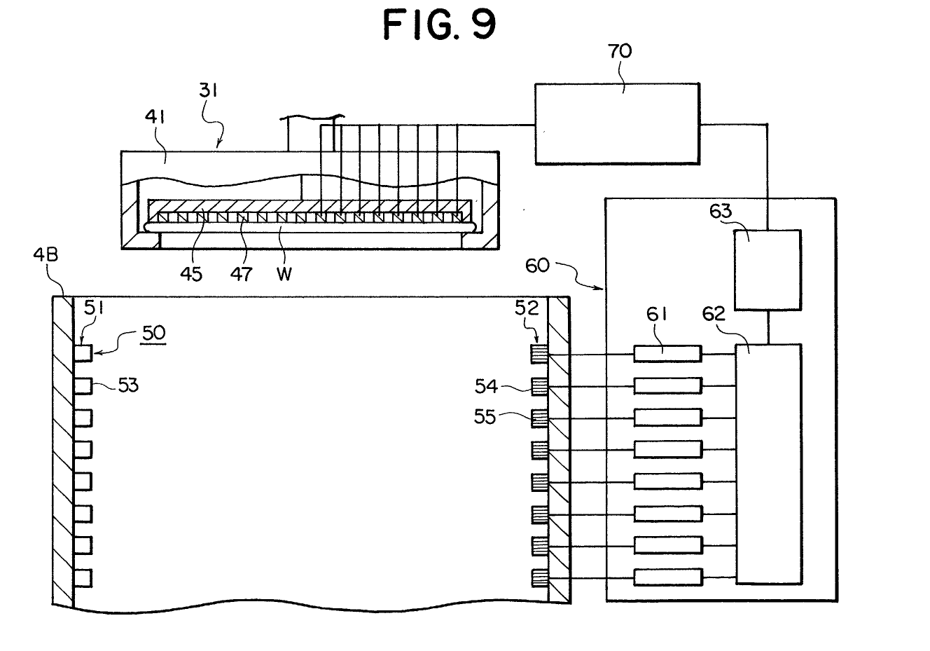

FIG. 9 is a schematic view showing the inside of the plating apparatus 1 according to the embodiment. As shown in FIG. 9, on an inner wall of the inner tank 4B, a film thickness measurer 50 (solution processing measurer) for measuring the film thickness while the plating is applied on the wafer W is provided. Specifically, the film thickness measurer 50 is composed of, for example, a light emitting member 51 for emitting the light such as a laser to the plating being applied on the face to be plated of the wafer W, and a light detecting member 52 for detecting the light emitted from the light emitting member 51 and reflected by the plating.

The light emitting member 51 is composed of a plurality of light emitting members 53 for emitting the light to each part of the wafer W. The light emitting members 53 are disposed in a vertical direction of the plating solution tank 4. Further, the light emitted from each of the light emitting members 53 is preferably the light with such an emission peak wavelength as is reflected by the plating applied on the wafer W. Furthermore, each of the light emitting members 53 directs the light to the center part across the outer circumference of the wafer W substantially at regular intervals.

The light detecting member 52 is composed of a plurality of light detecting members 54 for measuring the reflected light from each part of the wafer W. The light detecting members 54 are disposed at positions opposing to the light emitting members 53 in equal numbers. Each of the light detecting members 54 is a multi-channel-type light detector and composed of a plurality of sensors 55 for detecting the reflected light and converting it into an electric signal.

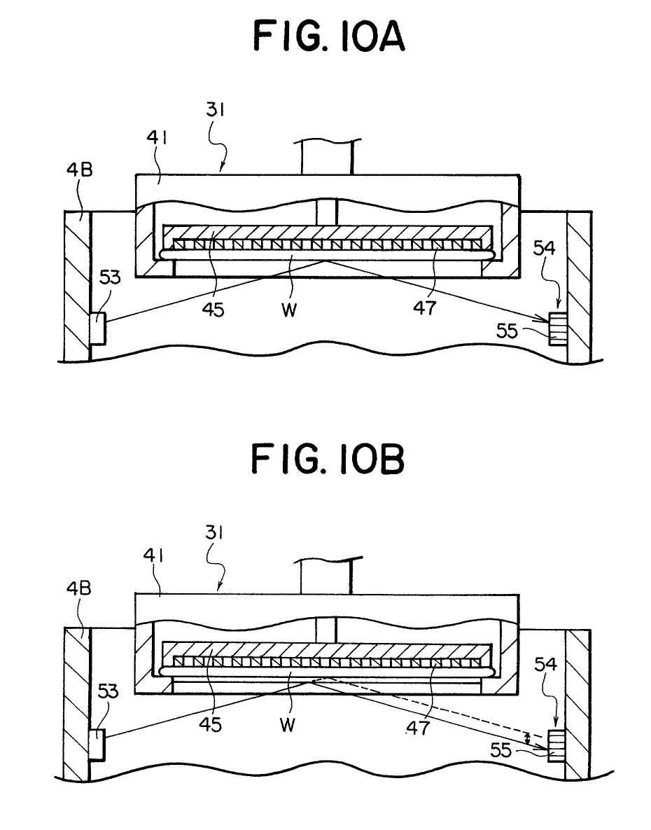

A measurement method for specifically measuring the film thickness of the wafer W will be explained below with reference to FIG. 10A and FIG. 10B. FIG. 10A and FIG. 10B are schematic views showing states of measuring the film thickness of the wafer W according to the embodiment. First, as shown in FIG. 10A, in a state that a very small quantity of plating is applied, each of the light emitting members 53 emits the light to the face to be plated of the wafer W so that the light is reflected by the plating. Each of the light detecting members 54 detects the reflected light reflected by the plating. Thereafter, in a state that the plating is applied thicker than before, each of the light emitting members 53 emits the light again at the same angle so that the light is reflected by the plating. Then, each of the light detecting members 54 detects the reflected light in the same way. Here, the reflected light moves downward as shown in FIG. 10B. The change of the position of the reflected light varies a detection value detected by each of the sensors 55, which enables each of the light detecting members 54 to measure the film thickness.

To the light detecting members 54, a calculator 60 for sequentially calculating the film thickness, film-formation speed, and optimal temperature of each part of the wafer W based on a result detected by each of the light detecting members 54 is electrically connected.

The calculator 60 is composed of film thickness calculators 61 for calculating the film thickness of each part of the wafer W based on the electric signals outputted from the sensors 55, a film-formation speed calculator 62 for calculating the optimal film-formation speed of each part of the wafer W from the film thickness calculated in the film thickness calculators 61, and an optimal temperature calculator 63 for calculating the optimal temperature of each part of the wafer W from the optimal film-formation speed calculated in the film-formation speed calculator 62. To the optimal temperature calculator 63, a resistance heating element controller 70 is electrically connected. The resistance heating element controller 70 according to the embodiment controls each of the resistance heating elements 47 so that the temperature of each part of the wafer W becomes the optimal temperature calculated in the optimal temperature calculator 63.

The calculation performed in the film-formation speed calculator 62 and the optimal temperature calculator 63 will be explained below.

It should be noted that two points of the wafer W, that is, the center part and the outer circumference will be explained to simplify the explanation.

First, a relational expression between the temperature and the film thickness is calculated in advance by measuring the dummy wafer. Further, the desired film thickness xₙ and the achievement time tₙ for achieving the desired film thickness xₙ are set.

The film thickness of the center part is defined as x_{A1} and the film thickness of the outer circumference is defined as X_{B1} at the time t₁. Similarly, the film thickness of the center part is defined as x_{A2}, x_{A3}, . . . x_{Ai}, . . . x_{An}, and the film thickness of the outer circumference is defined as x_{B2}, x_{B3}, . . . x_{Bi}, . . . x_{Bn}, at the time t₂, t₃, . . . tᵢ, . . . tₙ. It should be noted that x_{An} is the final film thickness of the center part and x_{Bn} is the final film thickness of the outer circumference. Further, the uniformity of the plating improves as values of x_{An} and x_{Bn} become closer, and therefore it is assumed that there is the relation as expressed in the following formula (1) between x_{An} and x_{Bn}.

x_{An}=x_{Bn} (1)

In addition, the final film thickness x_{An} of the center part can be expressed by the following formula (2).

x_{An}=x_{Ai}+dx_{Ai}/dt(tₙ−tᵢ) (2)

Similarly, the final film thickness x_{Bn} of the outer circumference can be expressed by the following formula (3).

x_{Bn}=x_{Bi}+dx_{Bi}/dt(tₙ−tᵢ) (3)

From the above-described formulas (1) to (3), the relation expressed by the following formula (4) can be derived.

dx_{Ai}/dt=(x_{Ai}−x_{Bi})/(tₙ−tᵢ)+dx_{Bi}/dt (4)

In the formula (4), when the film-formation speed of the outer circumference is fixed, the optimal film-formation speed of the center part is determined. Incidentally, x_{Ai}−x_{Bi} and tₙ−tᵢ are constants.

Next, this optimal film-formation speed is substituted into the relational expression between the temperature and the film-formation speed so that the optimal temperature of the center part is calculated. By performing the calculation as described above for the film thickness of each part of the wafer W, the optimal temperature of each part can be calculated.

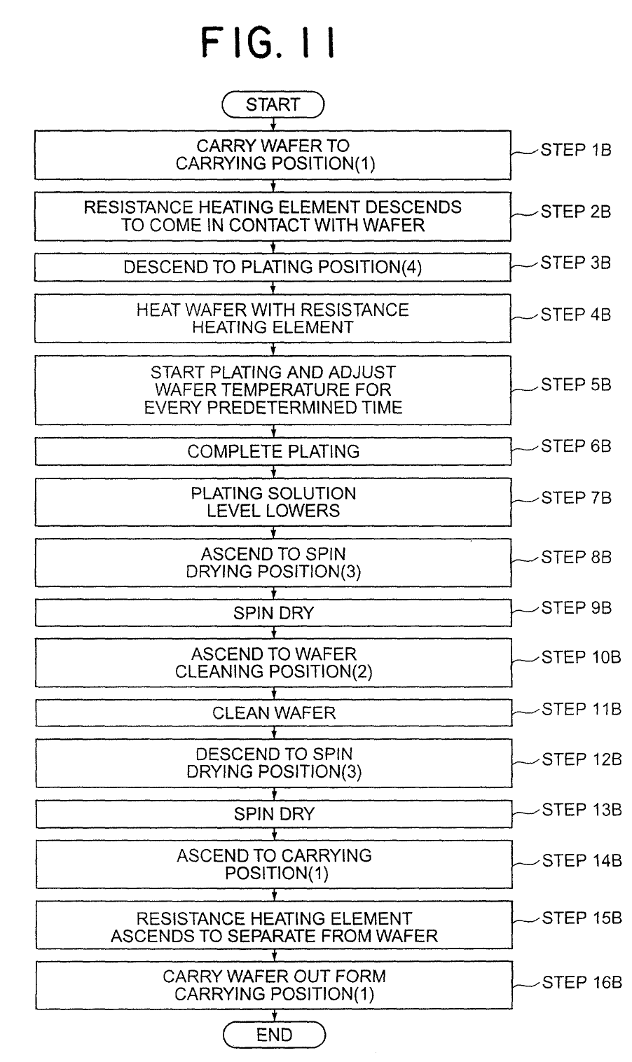

The flow of the plating processing in the plating apparatus 1 will be explained below with reference to FIG. 11. FIG. 11 is a flow chart showing the flow of the plating processing performed in the plating apparatus 1 according to the embodiment.

First, the unprocessed wafer W is positioned at the carrying position (1). Then, the resistance heating element holder 45 descends with respect to the holder container 41 so that the resistance heating element 46 comes in contact with the rear face of the wafer W ((Step 1B) and (Step 2B)).

Thereafter, the driver 3 descends by the drive of the cylinder 35 and the wafer W is positioned at the plating position (4). In this state, the wafer W is heated in a manner that the temperature of the wafer W becomes gradually higher from the outer circumference to the center part of the wafer W ((Step 3B) and (Step 4B)).

After the temperature of the wafer W is stabilized, in this state, voltage is applied between the anode electrode 22 and the wafer W so as to apply the plating on the face to be plated of the wafer W (Step 5B).

In this embodiment, the light is emitted from the light emitting member 53 to the plating applied on the wafer W while the plating is being applied. When the light is emitted to the plating, the light is reflected by a surface of the plating. The reflected light is detected by the sensors 55 of each of the light detecting members 54 and converted into the electric signal. The electric signal is transmitted to the film thickness calculator 61 and the film thickness is calculated in the film thickness calculator 61. Thereafter, the film thickness calculated in the film thickness calculator 61 is transmitted to the film-formation speed calculator 62 as electric signal so that the optimal film-formation speed is calculated. Further, the optimal film-formation speed calculated in the film-formation speed calculator 62 is transmitted to the optimal temperature calculator 63 as an electric signal so that the optimal temperature is calculated. The optimal temperature calculated in the optimal temperature calculator 63 is transmitted to the resistance heating element controller 70 as an electric signal. Based on this electric signal, the resistance heating element controller 70 controls each of the resistance heating elements 47 so that the temperature of each part of the wafer W becomes the optimal temperature. This operation is repeatedly performed for every predetermined time.

As described above, in this embodiment, the film thickness of each part of the wafer W is measured, the optimal temperature for improving the uniformity of the plating is calculated based on the film thickness, and each of the resistance heating elements 47 is controlled so that each part of the wafer W becomes at the calculated optimal temperature while the plating is being applied on the wafer W, which can further improve the uniformity of the plating.

After the plating of sufficient thickness is applied on the face to be plated of the wafer W, the heating by each of the resistance heating elements 47 is stopped as well as the application of the voltage is stopped so as to complete the application of the plating (Step 6B).

Subsequently, the plating solution level in the plating solution tank 4 is lowered and the wafer W is positioned at the spin drying position (3) to perform spin drying ((Step 7B) to (Step 9B)).

After the spin drying is performed sufficiently, the wafer W is positioned at the wafer cleaning position (2) to clean the plating applied on the wafer W ((Step 10B) and (Step 11B)).

After the plating applied on the wafer W is cleaned, the wafer W is positioned at the spin drying position (3) to perform spin drying ((Step 12B) and (Step 13B)).

After the spin drying is performed sufficiently, the wafer W is positioned at the carrying position (1) and the resistance heating element 46 separates from the wafer W. Then, the wafer W is carried out from the plating apparatus 1 ((Step 14B) to (Step 16B)).

(Third Embodiment)

The third embodiment of the present invention will be explained below.

In this embodiment, an example of plating the wafer in a so-called face-up method in which the face to be plated of the wafer is directed upward will be explained.

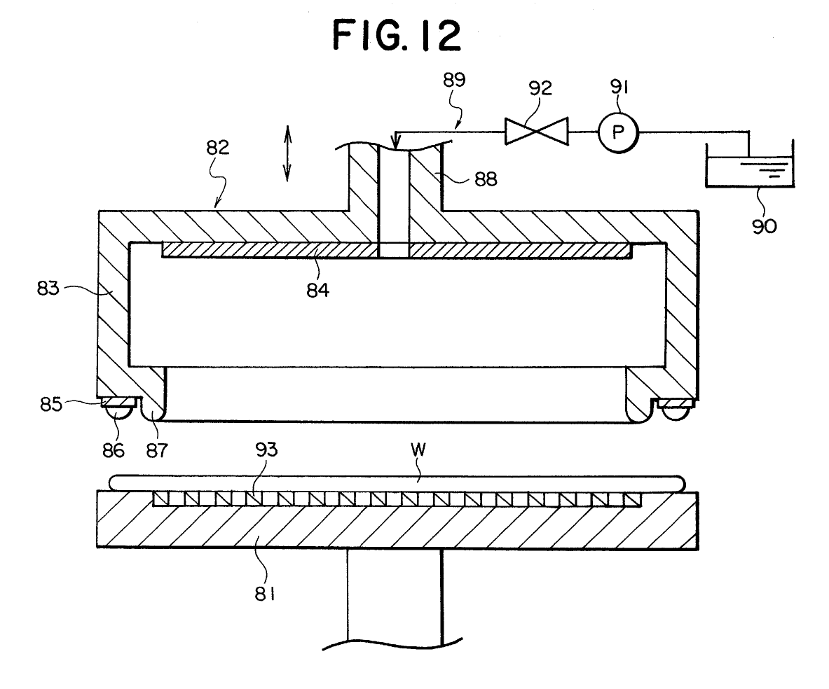

FIG. 12 is a schematic view showing the inside of the plating apparatus 1 according to the embodiment. As shown in FIG. 12, in the plating apparatus 1 of the embodiment, disposed are a rotatable table 81 on which the wafer W is placed with its face to be plated being directed upward, and a voltage application member 82 for applying voltage to the face to be plated of the wafer W which is placed on the table 81.

The voltage application member 82 forms a plating solution tank by combining with the table 81. The voltage application member 82 includes an electrode holder 83 for holding an anode electrode 84 and a cathode electrode 85 which will be described later. The electrode holder 83 is formed in a substantially cylindrical shape with its upper face being closed and its bottom face being open.

In the electrode holder 83, the anode electrode 84 in a discoidal shape is disposed, and on the bottom face of the electrode holder 83, the cathode electrode 85 in a ring shape is disposed. On the cathode electrode 85, semi-spherical contacts 86 are provided to protrude downward, similarly to the first embodiment. Further, on an edge of the opening of the bottom face of the electrode holder 83, a seal portion 87 is formed.

To an upper part of the electrode holder 83, an introduction pipe 88 for introducing the plating solution into the electrode holder 83 is connected. To the introduction pipe 88, a plating solution supplying system 89 for supplying the plating solution is connected. Specifically, the plating solution supplying system 89 is composed of, for example, a tank 90 for containing the plating solution therein, a pump 91 for pumping the plating solution out from the tank 90 and returning the plating solution to the tank 90, and a valve 92 for adjusting a flow rate of the plating solution.

Moreover, on the introduction pipe 88, the aforesaid supporting beams 33 for supporting the voltage application member 82 are mounted. By the drive of the cylinder 35, the voltage application member 82 supported by the supporting beams 33 ascends/descends along the guide rail 34.

In the table 81, a resistance heating element 93 is disposed. The resistance heating element 93 heats the wafer W from the rear face of the wafer W so as to perform zone control of the temperature of the wafer W, similarly to the first embodiment.

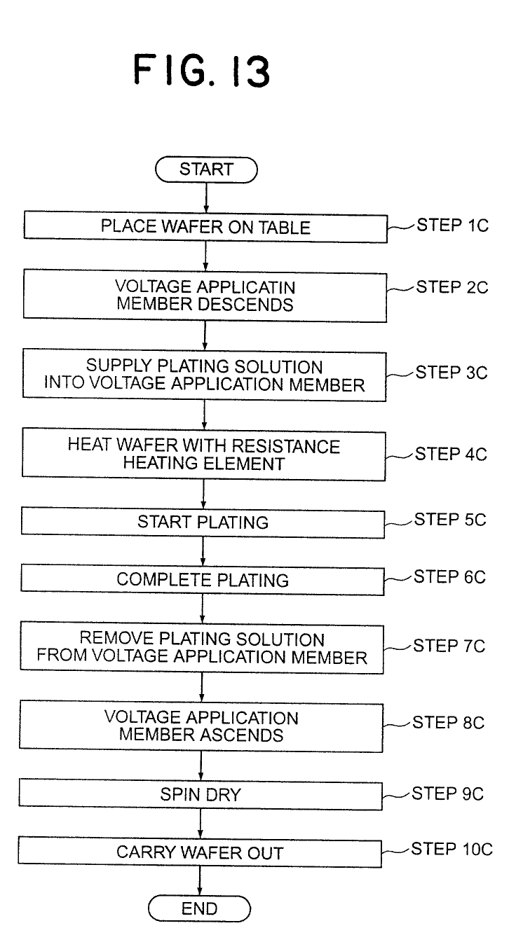

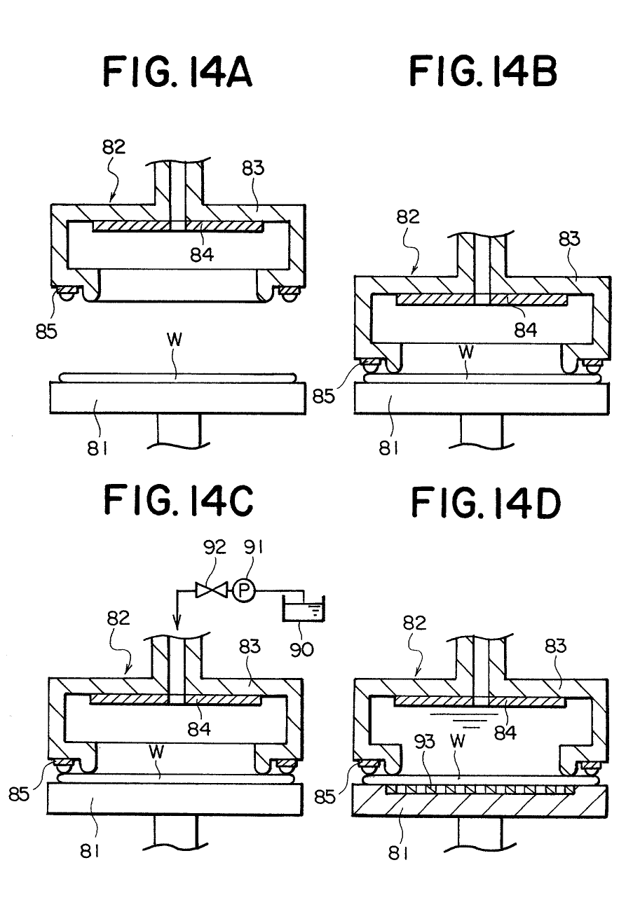

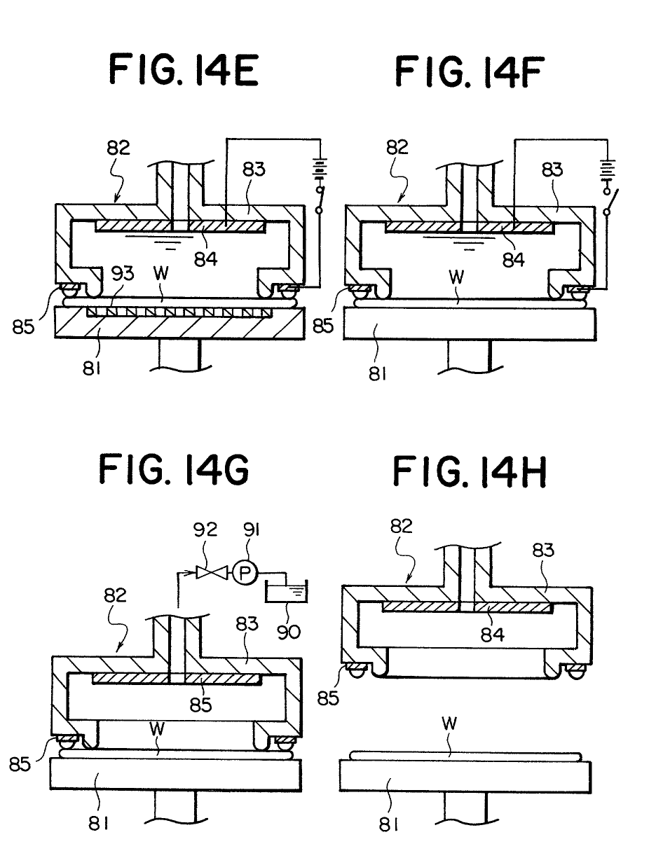

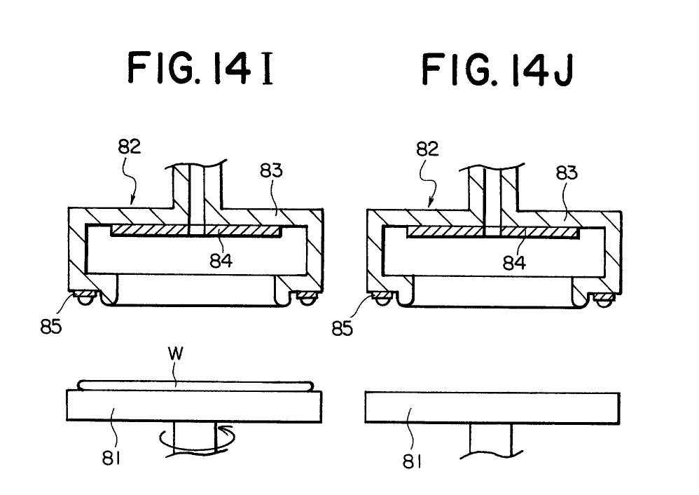

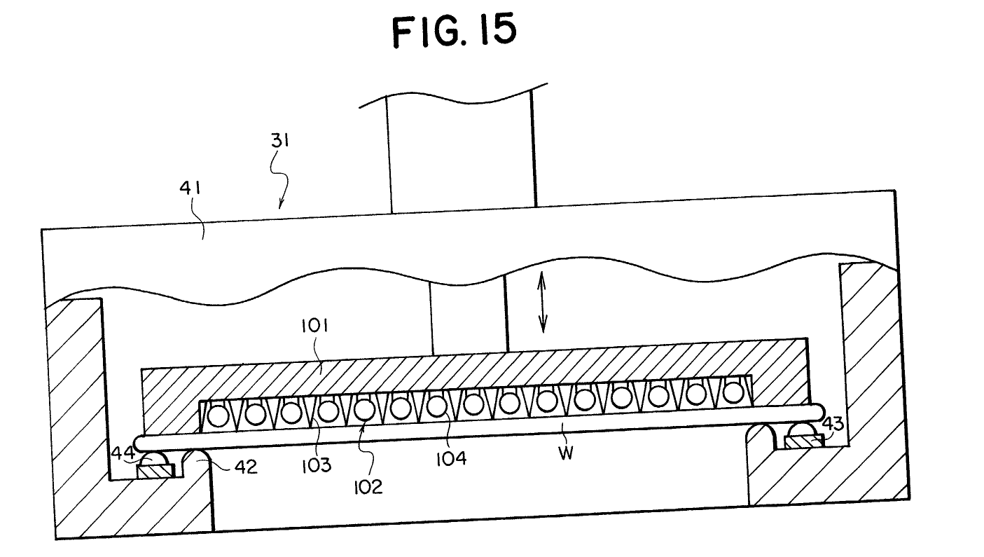

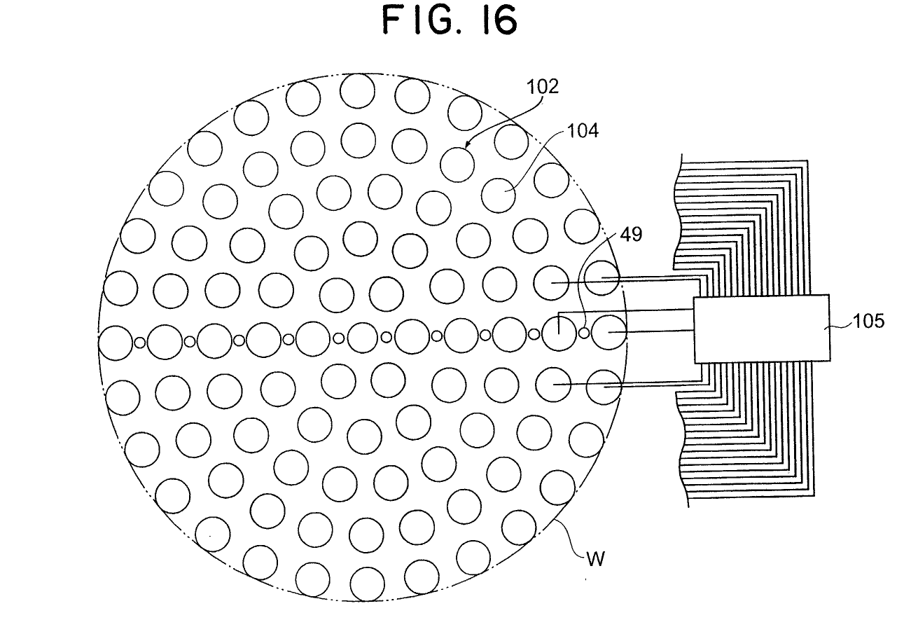

The flow of the plating processing in the plating apparatus 1 will be explained below with reference to FIG. 13 and FIG. 14A to FIG. 14J. FIG. 13 is a flow chart showing the flow of the plating processing performed in the plating apparatus 1 according to the embodiment, and FIG. 14A to FIG. 14J are schematic views showing plating steps according to the embodiment.

First, as shown in FIG. 14A, the unprocessed wafer W is placed substantially horizontally on the table 81 with its face to be plated being directed upward (Step 1C).

In this state, as shown in FIG. 14B, the electrode holder 83 descends by the drive of the cylinder 35 and the contacts 86 come in contact with the face to be plated of the wafer W (Step 2C).

After the contacts 86 come in contact with the face to be plated of the wafer W, the pump 91 operates and the valve 92 opens so that the plating solution is supplied from the tank 90 into the electrode holder 83 via the introduction pipe 88, as shown in FIG. 14C (Step 3C).

After the plating solution is supplied into the electrode holder 83, as shown in FIG. 14D, the wafer W is heated so that the temperature of the wafer W becomes gradually higher from the outer circumference to the center part of the wafer W (Step 4C).

After the temperature of the wafer W is stabilized, in this state, voltage is applied between the anode electrode 84 and the wafer W to apply the plating on the face to be plated of the wafer W, as shown in FIG. 14E (Step 5C).

After the plating of sufficient thickness is applied on the face to be plated of the wafer W, as shown in FIG. 14F, the heating by the resistance heating element 93 is stopped as well as the application of the voltage is stopped so as to complete the application of the plating (Step 6C).

Subsequently, as shown in FIG. 14G, the plating solution is sucked from the electrode holder 83 by the operation of the pump 92 so that the plating solution is returned into the tank 90 (Step 7C).

After the plating solution is returned to the tank 90, the voltage application member 82 ascends by the drive of the cylinder 35, as shown in FIG. 14H (Step 8C).

In this state, the table 81 is rotated to perform spin drying, as shown in FIG. 14I (Step 9C).

After the spin drying is sufficiently performed, the rotation of the table 81 is stopped and, as shown in FIG. 14J, the wafer W is carried out from the plating apparatus 1 (Step 10C).

(Fourth Embodiment)

The fourth embodiment of the present invention will be explained below.

In this embodiment, an example of heating the wafer with heating lumps will be explained.

FIG. 15 is a schematic vertical sectional view showing a holder according to the embodiment, and FIG. 16 is a schematic plan view showing the inside of the holder according to the embodiment. As shown in FIG. 15 and FIG. 16, in a holder container 41 of the embodiment, a heating lump holder 101 for holding a heating lump 102 and reflecting elements 103, which will be next explained, and capable of ascending/descending with respect to the holder container 41 is disposed.

In the heating lump holder 101, the heating lump 102 (heating member) for heating the rear face of the wafer W is disposed. Around the heating lump 102, the reflecting elements 103 in a truncated cone shape for reflecting the light of the heating lump 102 and directing it to the rear face of the wafer W are disposed.

The heating lump 102 is composed of a plurality of heating lumps 104. To the heating lump 102, a heating lump controller 105 (heating member controller) disposed outside the housing 2 for controlling the heating lump 102 is electrically connected. Specifically, the heating lump controller 105 is electrically connected to, for example, each of the heating lumps 104 and able to vary heating values for each of the heating lumps 104.

As described above, in the plating apparatus 1 according to the embodiment, the heating of the wafer W is performed with the heating lump 102, which can enhance the rising speed of the temperature of the wafer W and allow each part of the wafer W to reach the optimal temperature more quickly. In addition, more precise zone control becomes possible.

(Fifth Embodiment)

The fifth embodiment of the present invention will be explained below.

In this embodiment, an example of cooling the wafer to apply the plating and thereafter heating the wafer to further apply the plating will be explained.

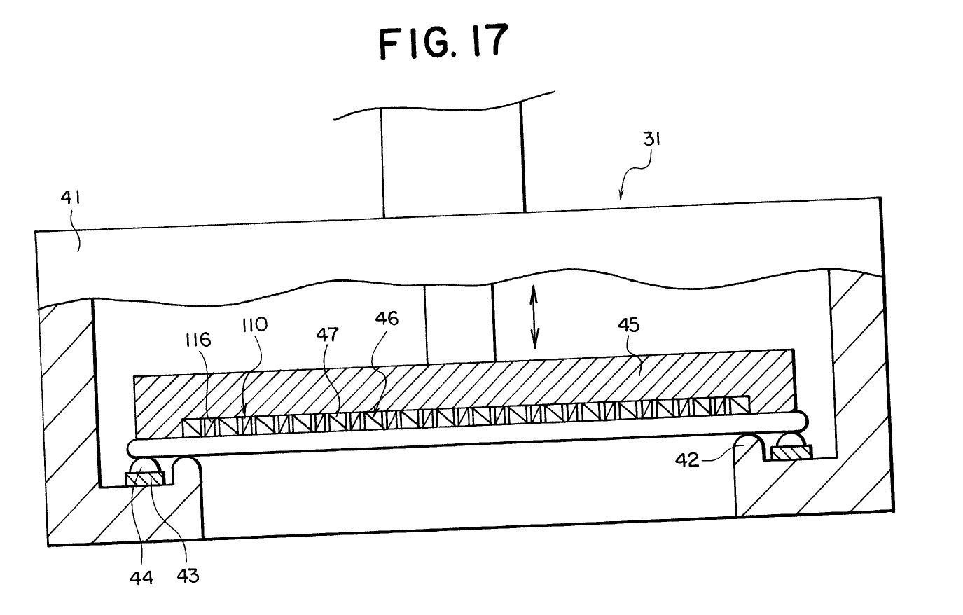

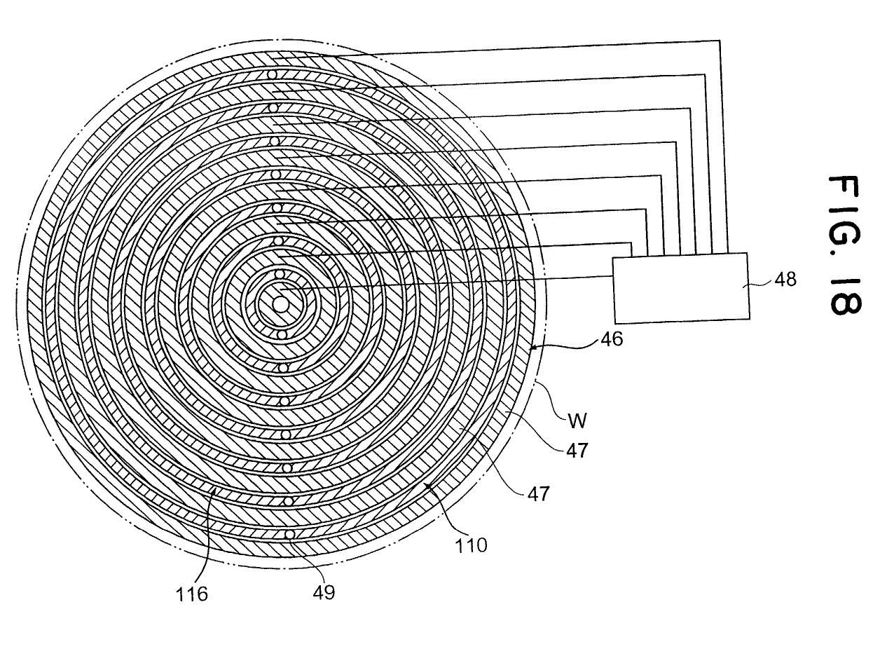

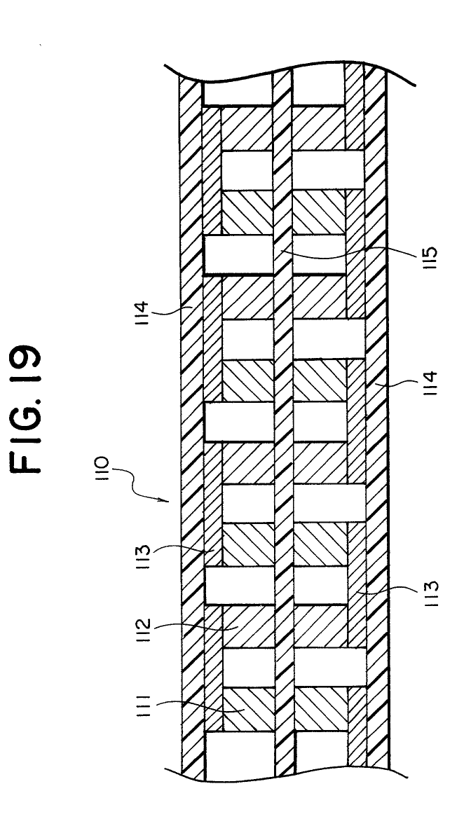

FIG. 17 is a schematic vertical sectional view showing a holder according to the embodiment, FIG. 18 is a schematic plan view showing the inside of the holder according to the embodiment, and FIG. 19 is a schematic vertical sectional view showing a Peltier element according to the embodiment.

As shown in FIG. 17 to FIG. 19, a Peltier element 110 (cooling member) coming in direct contact with the rear face of the wafer W is disposed in the resistance heating element holder 45 and between each of the resistance heating elements 47. By disposing the Peltier element 110, the wafer W is cooled to the predetermined temperature.

The Peltier element 110 is composed of p-type thermo-conductive material 111 such as (Bi_{0.25}Sb_{0.75})₂Te₃, n-type thermo-conductive material 112 such as Bi₂(Te_{0.95}Se_{0.05})₃, pairs of electrodes 113 connected to the p-type thermo-conductive material 111 and the n-type thermo-conductive material 112, a pair of insulating synthetic resin films 114 covering an outside surface of each of the electrodes 113, and a separator 115 formed of, for example, glass epoxy for supporting the p-type thermo-conductive material 111 and the n-type thermo-conductive material 112. By supplying current to the p-type thermo-conductive material 111 and the n-type thermo-conductive material 112 via the electrodes 113, the cooling action can be realized.

Since the synthetic resin films 114 are used as material for covering the outside surface of each of the electrodes 113, the flexibility improves as well as cooling efficiency improves. The Peltier element 110 has an advantage that it has high reliability and can be provided at low cost compared with a general Peltier element.

Further, the Peltier element 110 is composed of a plurality of Peltier elements 116 formed in a ring shape. Each of the Peltier elements 116 is held inside the resistance heating element holder 45 centrically and substantially horizontally.

Each of the Peltier elements 116 is electrically connected with each other. Each of the Peltier elements 116 is electrically connected to a power source disposed outside the housing 2.

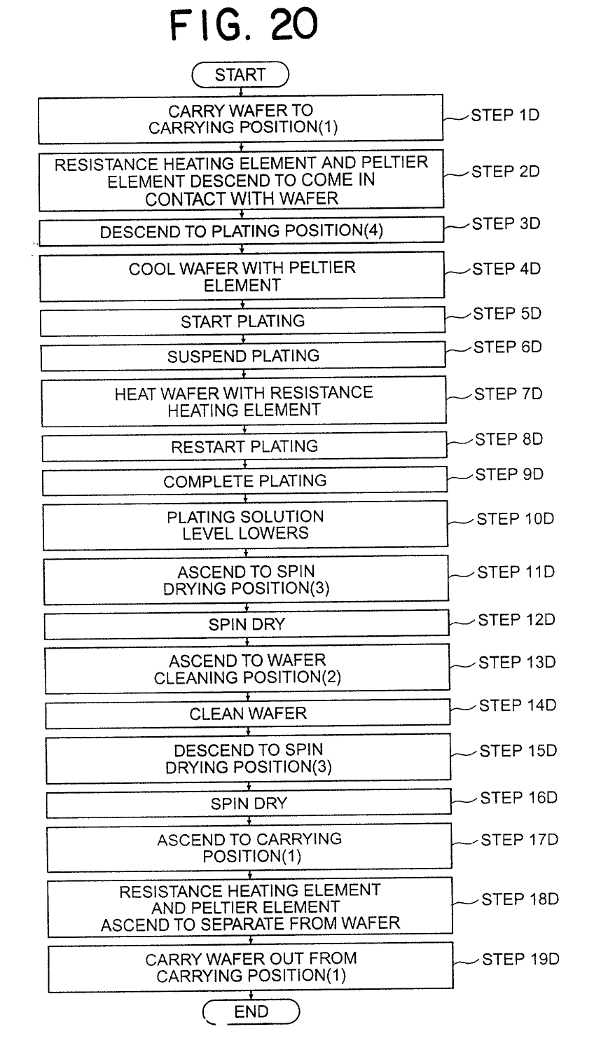

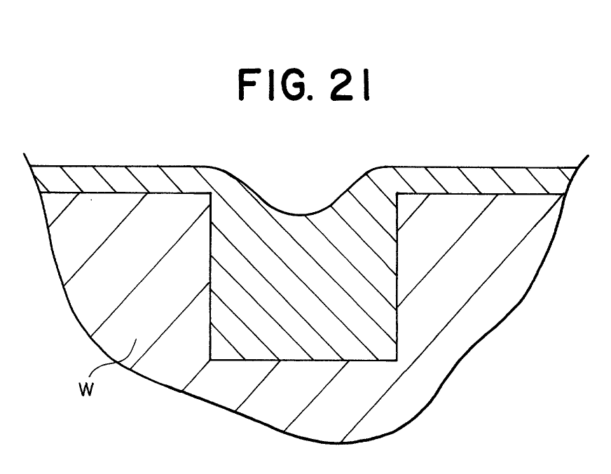

The flow of the plating processing in the plating apparatus 1 will be explained below with reference to FIG. 20 and FIG. 21. FIG. 20 is a flow chart showing the flow of the plating processing performed in the plating apparatus 1 according to the embodiment, and FIG. 21 is a schematic view showing a state of the plated wafer W according to the embodiment.

First, the unprocessed wafer W is positioned at the carrying position (1) substantially horizontally. Then, the resistance heating element holder 45 descends with respect to the holder container 41, and the resistance heating element 46 and the Peltier element 110 come in contact with the rear face of the wafer W ((Step 1D) and (Step 2D)).

Thereafter, the driver 3 descends by the drive of the cylinder 35 to position the wafer W at the plating position (4) (Step 3D).

In this state, the current is supplied to the electrodes 113 of the Peltier element 110 so that the wafer W is cooled to 15° C. or lower, preferably in the range of 5° C. to 15° C. (Step 4D). The temperature of the wafer W is specified as 15° C. or lower because, when the wafer W is at 15° C. or lower, voids are not easily produced in the slots and holes formed on the face to be plated of the wafer W.

After the temperature of the wafer W is stabilized, voltage is applied between the anode electrode 22 and the wafer W to apply the plating on the face to be plated of the wafer W (Step 5D).

In this embodiment, the plating is applied on the wafer W while cooling the wafer W, which can improve a filling property of the plating in the slots and holes formed on the face to be plated of the wafer W.

Specifically, by cooling the wafer W, the temperature of the wafer W falls. When the temperature of the wafer W falls, the moving speed of the ions around the wafer W is reduced, and the growing speed of the plating is reduced. Particularly, the growing speed of the plating in the part of the wafer W other than the slots and holes is more reduced than that in the slots and holes. Accordingly, as shown in FIG. 21, the plating can be surely filled into the slots and holes formed on the face to be plated of the wafer W, which reduces the voids to be produced in the slots and holes.

After the plating is sufficiently filled into the slots and holes, the cooling by the Peltier element 110 is stopped as well as the application of the voltage is stopped so as to suspend the application of the plating (Step 6D).

Then, the wafer W is heated by each of the resistance heating elements 47 so that the temperature of the wafer W becomes gradually higher from its outer circumference to its center part (Step 7D).

After the temperature of the wafer W is stabilized, in this state, voltage is applied between the anode electrode 22 and the wafer W to apply the plating on the plated face of the wafer W again (Step 8D). Here, the temperature of the center part and the outer circumference of the wafer W are, specifically, in the range of 18° C. to 30° C., for example. The temperature of the wafer W is specified as in the range described above because the growing speed of the plating increases effectively so that the plating is uniformly applied on the plated face of the wafer W in the range.

After the plating of sufficient thickness is applied on the plated face of the heated wafer W, the heating by each of the resistance heating elements 47 is stopped as well as the application of the voltage is stopped to complete the application of the plating (Step 9D).

Subsequently, the plating solution level in the plating solution tank 4 is lowered and the wafer W is positioned at the spin drying position (3) to perform spin drying ((Step 10D) to (Step 12D)).

After the spin drying is sufficiently performed, the wafer W is positioned at the wafer cleaning position (2) to clean the plating applied on the wafer W ((Step 13D) and (Step 14D)).

After the plating applied on the wafer W is cleaned, the wafer W is positioned at the spin drying position (3) to perform spin drying ((Step 15D) and (Step 16D)).

Then, the wafer W is positioned at the carrying position (1), the resistance heating element 46 and the Peltier element 110 are separated from the rear face of the wafer W, and the wafer W is carried out from the plating apparatus 1 ((Step 17D) to (Step 19D)).

It is to be understood that the present invention is not intended to be limited to the above description of the embodiments, and structures, material, arrangement of each member, or the like can be appropriately modified therein without departing from the spirit of the present invention. In the above-described first to fifth embodiments, the part which is easy to plate is explained as the outer circumference of the wafer W and the part which is difficult to plate is explained as the center part of the wafer W, but the present invention can be also applied to a case in which the plating is ununiformly applied because of a shape of the plating solution tank 4 or the like.

In the above-described first to fifth embodiments, the wafer W is used as a substrate, but an LCD glass substrate for liquid crystal can be also used.

In the above-described first to fifth embodiments, the plating processing is explained as solution processing, but the present invention can be applied to any processing with a solution.

In the above-described first to third embodiments and fifth embodiment, each of the resistance heating elements 47 is formed of one piece of a resistance heating element, but it can be divided into plural pieces. In this case, the resistance heating element controller 48 is electrically connected to each divided part. By dividing each of the resistance heating elements 47, more precise zone control can be performed.

In the above-described first embodiment, second embodiment, fourth embodiment, and fifth embodiment, the cathode electrode 43 is disposed in the holder 31, but it can be disposed on a plating solution tank 4 side. Specifically, the cathode electrode 43 is disposed, for example, on an edge of the opening of the upper face of the inner tank 4B. In this case, the holder container 41 is unnecessary, and the wafer W is held by providing an attraction portion for attracting the rear face of the wafer W on the resistance heating element holder 45 or the heating lump holder 101.

In the above-described second embodiment, the film thickness of each part of the wafer W is measured in the plating solution tank 4 while the plating is being applied to the wafer W, but it is also possible to measure the film thickness of each part of the wafer W by sheet resistance or x-rays after suspending the plating and taking the wafer W out from the plating solution tank 4. In this case, after the measurement of the film thickness, the wafer W is returned into the plating solution tank 4 and the optimal temperature is calculated based on the measurement result so that the plating is applied again on the wafer W at the optimal temperature.

In the above-described third to fifth embodiments, the optimal temperature is previously obtained and the temperature of each part of the wafer W is controlled to the optimal temperature, as described in the first embodiment, but it is also possible to calculate the optimal temperature from the film thickness and control the temperature of each part of the wafer W to the optimal temperature while the plating is being applied, as described in the second embodiment.

In the above-described fifth embodiment, the plating is applied on the wafer W in two stages by changing the temperature, but any number of stages can be employed.

In the above-described fifth embodiment, the Peltier element 110 is used as the cooling member, but the general Peltier element can be also used. Further, as the cooling member, other members having a cooling function can be also used.

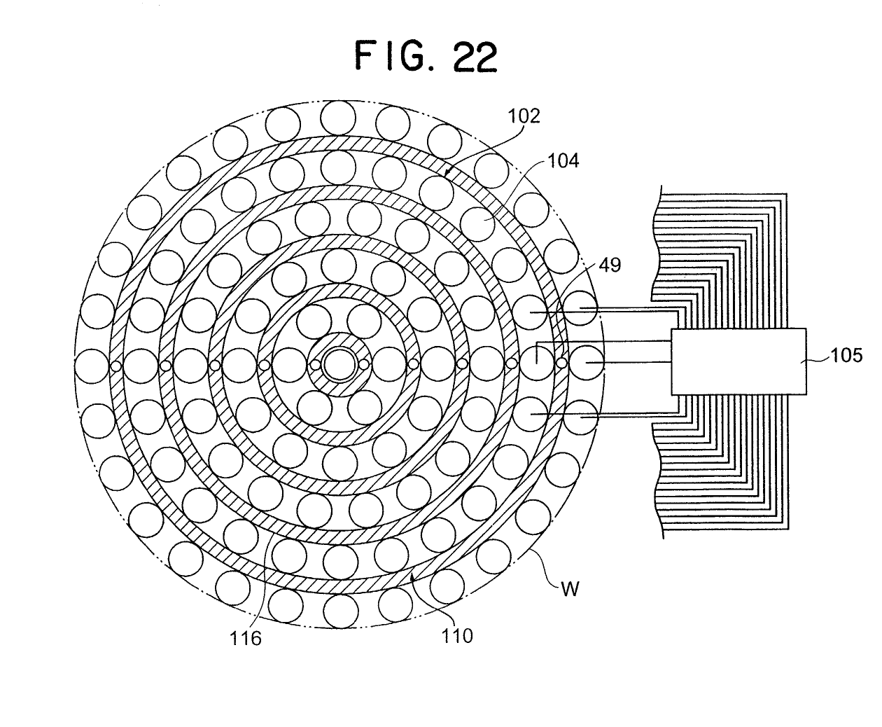

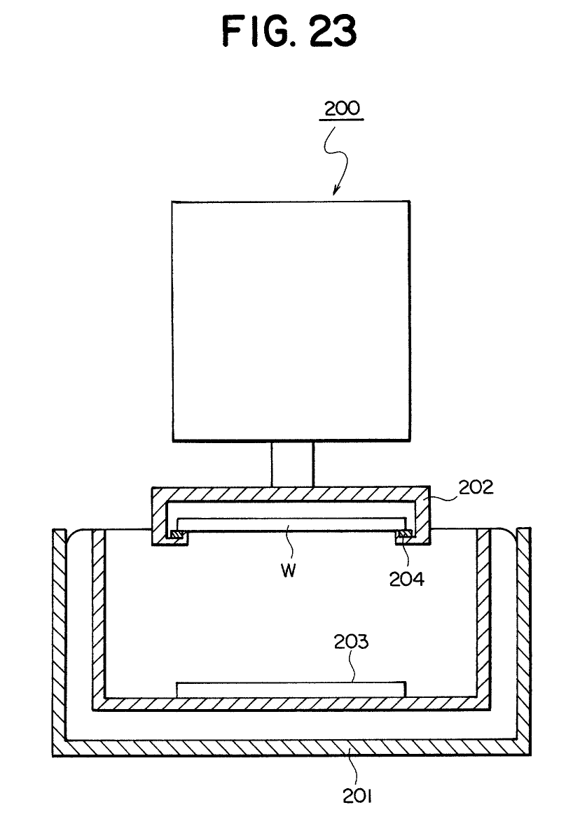

In the above-described fifth embodiment, the Peltier element 110 is disposed between each of the resistance heating elements 47, but as shown in FIG. 22, the Peltier element 110 can be also disposed between the heating lumps 104 described in the aforesaid fourth embodiment.

What is claimed is:

1. A solution processing apparatus, comprising:
a processing solution tank for containing a processing solution therein;
a holder for holding a substrate;
a first electrode coming in contact with the substrate held by said holder;
a second electrode between which and said first electrode voltage is applied; and
a temperature adjusting mechanism disposed in said holder for adjusting temperature of the substrate.

2. The solution processing apparatus according to claim 1,
wherein said temperature adjusting mechanism includes a heating member for heating the substrate.

3. The solution processing apparatus according to claim 1,
wherein said temperature adjusting mechanism includes a cooling member for cooling the substrate.

4. The solution processing apparatus according to claim 2,
wherein said temperature adjusting mechanism includes a heating member controller for controlling the heating member in a manner in which temperature of a part where solution processing is difficult becomes higher than temperature of a part where solution processing is easy.

5. The solution processing apparatus according to claim 4, further comprising:
a solution processing measurer for measuring degrees of solution processing performed on the part where solution processing is easy and solution processing performed on the part where solution processing is difficult; and
an optimal temperature calculator for calculating optimal temperature of the part where solution processing is difficult based on a measurement result of the solution processing measurer,
wherein the heating member controller controls the heating member in a manner in which the temperature of the part where solution processing is difficult becomes the optimal temperature.

6. The solution processing apparatus according to claim 4,
wherein the part where solution processing is easy is an outer circumference of the substrate, and the part where solution processing is difficult is a center part of the substrate.

7. The solution processing apparatus according to claim 2,
wherein the heating member is formed in a ring shape.

8. The solution processing apparatus according to claim 2,
wherein a plurality of the heating members are disposed.

9. The solution processing apparatus according to claim 2,
wherein the substrate is a semiconductor wafer, and the heating member heats a rear face of the semiconductor wafer.

10. The solution processing apparatus according to claim 2,
wherein the heating member is a resistance heating element.

11. The solution processing apparatus according to claim 2,
wherein the heating member is a heating lump.

12. The solution processing apparatus according to claim 1,
wherein the processing solution is a plating solution.

13. A solution processing method, comprising:
a heating solution processing step of heating the substrate and supplying current to the substrate to perform solution processing on the substrate in a state in which a substrate is in contact with a processing solution.

14. A solution processing method, comprising:
a cooling solution processing step of cooling the substrate and supplying current to the substrate to perform solution processing on the substrate in a state in which a substrate is in contact with a processing solution; and
a heating solution processing step of heating the substrate and supplying the current to the substrate to perform solution processing on the substrate in a state in which the substrate on which solution processing has been performed is in contact with the processing solution.

15. The solution processing method according to claim 14,
wherein said cooling solution processing step is a step of cooling the substrate in a manner in which temperature of the substrate becomes 5° C. to 15° C., and said heating solution processing step is a step of heating the substrate in a manner in which the temperature of the substrate becomes 18° C. to 30° C.

16. The solution processing method according to claim 13,
wherein said heating solution processing step is performed in a state in which temperature of a part of the substrate where solution processing is difficult is higher than temperature of a part of the substrate where solution processing is easy.

17. The solution processing method according to claim 14,
wherein said heating solution processing step is performed in a state in which temperature of a part of the substrate where solution processing is difficult is higher than temperature of a part of the substrate where solution processing easy.

18. The solution processing method according to claim 16,
wherein said heating solution processing step includes:
a solution processing measuring step of measuring degrees of solution processing performed on the part where solution processing is easy and solution processing performed on the part where solution processing is difficult;
an optimal temperature calculating step of calculating an optimal temperature of the part where solution processing is difficult based on a measurement result of the solution processing measuring step; and
a heating controlling step of controlling heating in a manner in which temperature of the part where solution processing is difficult becomes the optimal temperature calculated in the optimal temperature calculating step.

19. The solution processing method according to claim 17,
wherein said heating solution processing step includes:
a solution processing measuring step of measuring degrees of solution processing performed to the part where solution processing is easy and solution processing performed on the part where solution processing is difficult;
an optimal temperature calculating step of calculating an optimal temperature of the part where solution processing is difficult based on a measurement result of the solution processing measuring step; and
a heating controlling step of controlling heating in a manner in which temperature of the part where solution processing is difficult becomes the optimal temperature calculated in the optimal temperature calculating step.

20. The solution processing method according to claim 16,
wherein the part where solution processing is easy is an outer circumference of the substrate, and the part where solution processing is difficult is a center part of the substrate.

21. The solution processing method according to claim 17,
wherein the part where solution processing is easy is an outer circumference of the substrate, and the part where solution processing is difficult is a center part of the substrate.
